(19) United States
(12) Patent Application Publication
(10) Pub. No.: US 2018/0276557 A1
(43) Pub. Date: Sep. 27, 2018

(54) INFORMATION PROCESSING DEVICE, INFORMATION PROCESSING SYSTEM, AND INFORMATION PROCESSING METHOD

(71) Applicant: Toshiba Memory Corporation, Minato-ku (JP)

(72) Inventors: Tetsufumi Tanamoto, Kawasaki (JP); Yusuke Higashi, Zushi (JP); Takao Marukame, Chuo (JP); Shinichi Yasuda, Setagaya (JP); Jun Deguchi, Kawasaki (JP)

(73) Assignee: Toshiba Memory Corporation, Minato-ku (JP)

(21) Appl. No.: 15/700,512

(22) Filed: Sep. 11, 2017

(30) Foreign Application Priority Data
Mar. 24, 2017 (JP) 2017-059940

(51) Int. Cl. G06N 99/00; G11C 11/16; H03K 3/38

(52) U.S. Cl. CPC G06N 99/002; G06N 7/005; H03K 3/38; G11C 11/1659

(57) ABSTRACT

According to one embodiment, a quantum annealing machine 1 includes a quantum bit array 21 which includes a plurality of cells (quantum bits) 211 respectively including a floating gate 105, and a controller 10 which executes writing of data in the plurality of cells 211, and temporally controls tunneling of an electric charge with respect to the floating gate 105.

### CROSS-REFERENCE TO RELATED APPLICATIONS

This application is based upon and claims the benefit of priority from Japanese Patent Application No. 2017-059940, filed on Mar. 24, 2017; the entire contents of all of which are incorporated herein by reference.

### FIELD

Embodiments described herein relate generally to an information processing device, an information processing system, and an information processing method.

### BACKGROUND

Recently, study of a quantum annealing machine has progressed as a method of solving an optimization problem in cooperation with artificial intelligence. Quantum annealing quantitatively expands a classic annealing calculation method, and is expected to reduce calculation time in a so-called NP-hard problem such as a traveling salesman problem.

### BRIEF DESCRIPTION OF THE DRAWINGS

FIG. 1 shows diagrams illustrating an example of a composition of a traveling salesman problem;

FIG. 2 is a diagram illustrating an example in which an influence of a tunneling term in an ising Hamiltonian equation of a first embodiment is gradually reduced according to an elapse of time;

FIG. 3 is a block diagram illustrating a schematic configuration example of a quantum annealing machine as an information processing device according to the first embodiment;

FIG. 4 is a block diagram illustrating a schematic configuration example of a quantum bit arithmetic unit according to the first embodiment;

FIG. 5 is a diagram illustrating a schematic configuration example of a quantum bit array illustrated in FIG. 4;

FIG. 6 is a diagram illustrating a configuration example of a cell (a quantum bit) according to the first embodiment;

FIG. 7 is a top view illustrating an example of a cell array having an NAND structure in a column direction according to the first embodiment;

FIG. 8 is a diagram illustrating an example of a capacitance network model according to the first embodiment;

FIG. 9 is a diagram illustrating an example of a calculation result in a case where a gate voltage is not applied to a control gate of a central cell in a capacitance network model exemplified in FIG. 8;

FIG. 10 is a diagram illustrating an example of electronic traffic according to the first embodiment;

FIG. 11 is a diagram illustrating another example of the electronic traffic according to the first embodiment;

FIG. 12A is an energy band diagram for illustrating an aspect in which tunneling of an electron occurs in a case where a gate voltage and a substrate voltage are not applied under a condition illustrated in FIG. 10;

FIG. 12B is an energy band diagram for illustrating an aspect in which tunneling of an electron occurs in a case where a positive gate voltage and a positive substrate voltage are applied under the condition illustrated in FIG. 10;

FIG. 12C is an energy band diagram for illustrating an aspect in which tunneling of an electron occurs in a case where a negative gate voltage and a negative substrate voltage are applied under the condition illustrated in FIG. 10;

FIG. 13 is a flowchart illustrating an example of a quantum arithmetic operation according to the first embodiment; and

FIG. 14 is a diagram illustrating a concept of a second embodiment, and is a diagram illustrating a configuration example of a cell (a quantum bit).

### DETAILED DESCRIPTION

In general, according to one embodiment, an information processing device includes a quantum bit array which includes a plurality of quantum bits respectively including a floating gate, and a controller which executes writing of data in the plurality of quantum bits and reading the data from the plurality of quantum bits, and temporally controls tunneling of an electric charge with respect to the floating gate.

Hereinafter, an information processing device, an information processing system, and an information processing method according to embodiments will be described in detail with reference to the accompanying drawings. Furthermore, the present invention is not limited to the following embodiments.

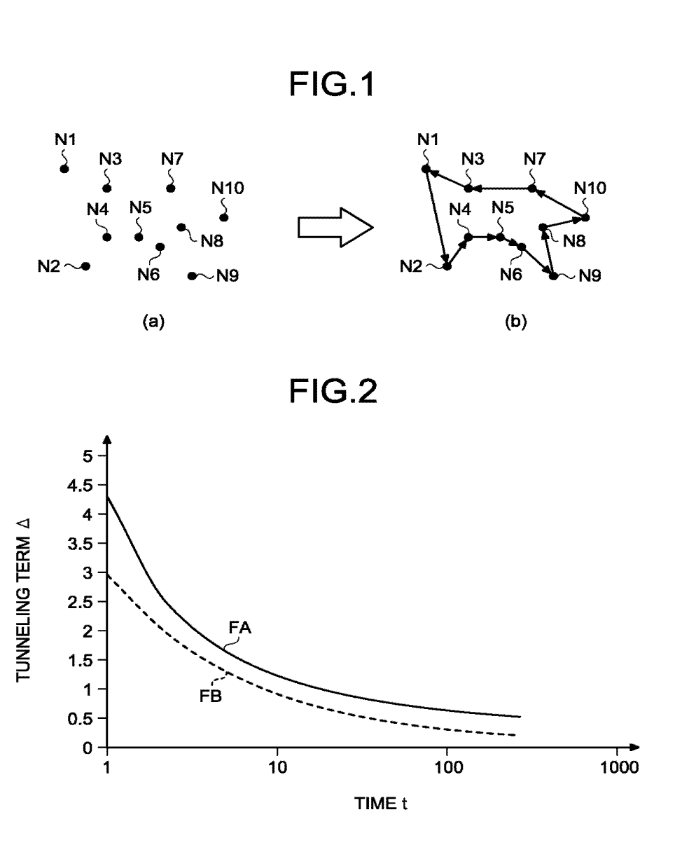

In the description of the following embodiment, first, a traveling salesman problem, which is one of representative optimization problems, will be described. FIGS. 1(a) and 1(b) are diagrams illustrating an example of a composition of the traveling salesman problem. FIG. 1(a) illustrates a relative position of ten cities N1 to N10 to be distributed. A distance between the respective cities is not constant, and is different. The traveling salesman problem is a problem of searching a route which efficiently travels all of the cities (in FIGS. 1(a) and 1(b), ten cities N1 to N10) to be dotted, and is one of the representative optimization problems which can be solved by a quantum annealing machine. A cost function in the traveling salesman problem is the length of the route (a route length) connecting all of the cities. Therefore, solving the traveling salesman problem corresponds to obtaining the shortest route in which the cost function is minimized.

For example, in a case where the traveling salesman problem illustrated in FIG. 1(a) is solved, as illustrated in FIG. 1(b)B, the cities N1 to N10 can be traveled in a sequence of N1→N2→N4→N5→N6→N9→N8→N10→N7→N3 (or the reverse sequence), and a solution, that is, the shortest route in which the cost function is minimized can be obtained. Furthermore, in FIGS. 1(a) and 1(b), a start point is set to the city N1.

An ising model is used for physically solving an engineering optimization problem. A ground state of the ising model corresponds to the solution of the optimization problem. In the optimization problem of obtaining the ground state of the ising model, Hamiltonian (energy) is the cost function. As represented in Expression (1) described below, classic ising Hamiltonian H includes a mutual interaction term Jᵢⱼ and a magnetic field term (a Zeeman term) hᵢ. In Expression (1), i and j respectively represent a grid point. In addition, sᵢ^{z} and sⱼ^{z} are respectively binary variable of either “+1” or “−1”.

$$H = {\sum }_{i < j} {J}_{ij} {s}_{i}^{z} {s}_{j}^{z} + {\sum }_{i} {h}_{i} {s}_{i}^{z} \qquad ( 1 )$$

In contrast, in quantum annealing, state searching is performed while performing superposition of various states by using a quantum tunneling effect due to a quantum fluctuation (hereinafter, simply referred to as a tunneling effect). Therefore, in an initial stage, an influence of the quantum fluctuation (a possession rate) increases, and thus, state searching is executed along with the superposition of a number of states, and after that, the strength of the quantum fluctuation is gradually reduced, and finally, a minimum state of the cost function is obtained.

In a case where the optimization problem of obtaining the ground state of the ising model is solved by the quantum annealing machine, as represented in Expression (2) described below, a tunneling term Δ controlling the strength and weakness of the tunneling effect due to the quantum fluctuation is added to the ising Hamiltonian H represented in Expression (1). Here, in a case of the quantum annealing, σᵢ^{z} and σⱼ^{z} of Expression (2) are not the binary variable, but are z component labeling of a spin which is represented by a Pauli matrix, and is allocated to the grid point i or j. Similarly, σᵢ^{x} is x component labeling of a spin which is allocated to the grid point i. Further, t is time.

$$H = {\sum }_{i < j} {J}_{ij} {σ}_{i}^{z} {σ}_{j}^{z} + {\sum }_{i} [ {h}_{i} {σ}_{i}^{z} + {Δ}_{i} ( t ) {σ}_{i}^{x} ] \qquad ( 2 )$$

In order to gradually reduce the strength of the quantum fluctuation, as represented in Expression (3) described below, the tunneling term Δ on a tail end of Expression (2) may be adjusted by being scheduled to be “0” as the time t elapses.

Δ(t→∞)→0 (3)

Here, FIG. 2 illustrates an example in which the influence of the tunneling term Δ of Expression (2) is gradually reduced along with an elapse of time. A curved line FA is an attenuation function of 1/log(1+t), and a curved line FB is an attenuation function of 1/√t. As illustrated in FIG. 2, the tunneling term Δ represented by the curved line FA or the curved line FB is scheduled to be attenuated along with the elapse of the time t.

Furthermore, in order to use the ising Hamiltonian H represented in Expression (2) described above as the quantum annealing machine, it is necessary that the Hamiltonian H can be freely processed. That is, it is necessary to have a configuration such that the mutual interaction term Jᵢⱼ and the magnetic field term hᵢ can be freely changed.

There is a quantum annealing machine using a superconductive quantum bit as the quantum annealing machine which is capable of solving the optimization problem as described above. However, in the quantum annealing machine, it is necessary to prepare a plurality of quantitatively coherent bits, and thus, in a configuration using a superconductive quantum circuit, such as the superconductive quantum bit, which is difficult to perform mass production, it is difficult to realize a device which is more excellent than the existing large-scale computer, including reliability.

Therefore, in the following embodiments, a quantum annealing machine is configured by using a floating gate (FG) type memory which is used in an established technology such as a NAND type flash memory. By using the FG type memory which is commercialized by establishing a production technology in advance as a base, it is possible to realize an information processing device as a quantum annealing machine having high mass productivity or high reliability, an information processing system, and an information processing method.

### First Embodiment

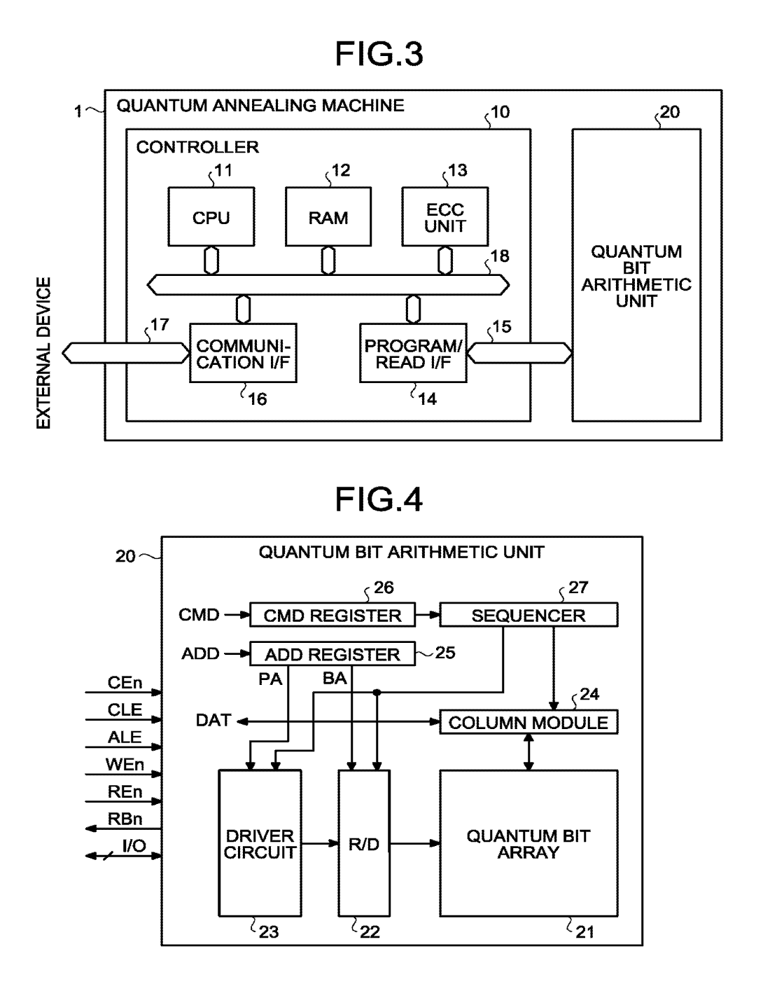

FIG. 3 is a block diagram illustrating a schematic configuration example of a quantum annealing machine 1 as an information processing device according to a first embodiment. The quantum annealing machine 1 includes a controller 10 and a quantum bit arithmetic unit 20.

The controller 10, for example, includes a communication interface circuit (a communication I/F) 16, a random access memory (RAM) 12, a central processing unit (CPU) 11, a program/read interface circuit (a program/read I/F) 14, and an ECC unit 13. The communication I/F 16, the RAM 12, the CPU 11, the program/read I/F 14, and the ECC unit 13 are connected to each other through an internal bus 18.

The communication I/F 16 is connected to an external device through an external bus 17, and executes transmitting and receiving of data with respect to the external device. Furthermore, the communication I/F 16 may be a network interface, and may be serial attached SCSI (SAS), serial ATA (SATA), PCI express (PCIe), or the like.

The CPU 11 controls the entire operation of the controller 10. For example, the CPU 11 issues a command of writing the data in the program/read I/F 14 at the time of setting the data with respect to the quantum bit arithmetic unit 20. In addition, the CPU 11 issues a command of reading the data from the program/read I/F 14 at the time of reading the data, which is an arithmetic result, from the quantum bit arithmetic unit 20. Further, the CPU 11 issues a command of erasing (resetting) the data from the program/read I/F 14 at the time of resetting the quantum bit arithmetic unit 20. In addition, the CPU 11 executes various processings for managing the quantum bit arithmetic unit 20 such as wear leveling.

The program/read I/F 14 is connected to the quantum bit arithmetic unit 20 through a NAND bus 15, and controls the writing and the reading of the data with respect to the quantum bit arithmetic unit 20 as an input signal I/O. The program/read I/F 14 outputs a signal ALE, a signal CLE, a signal WEn, and a signal REn to the quantum bit arithmetic unit 20, on the basis of a command received from the CPU 11. For example, the program/read I/F 14 transmits the written command, which is issued by the CPU 11, and the data, which is stored in the RAM 12 or the like, to the quantum bit arithmetic unit 20, at the time of writing the data. On the other hand, the program/read I/F 14 transmits the read command, which is issued by the CPU 11, to the quantum bit arithmetic unit 20, at the time of reading the data. Then, the program/read I/F 14 receives the data read from the quantum bit arithmetic unit 20, and transmits the data to the RAM 12.

The RAM 12, for example, is a semiconductor memory such as a dynamic RAM (DRAM, including a synchronous DRAM) or a static RAM (SRAM). Firmware for managing the quantum bit arithmetic unit 20, various management tables, and the like are loaded on the RAM 12. In addition, the RAM 12 functions as a working memory when the CPU 11 executes various arithmetics. Further, the RAM 12 functions as a buffer memory which temporally retains the data written in the quantum bit arithmetic unit 20 or the data read from the data quantum bit arithmetic unit 20.

The ECC unit 13 execute error detection and error correction with respect to the data. For example, the ECC unit 13 encodes the writing data in the quantum bit arithmetic unit 20. In addition, the ECC unit 13 decodes the data which is read from the quantum bit arithmetic unit 20, and thus, executes the error detection and the error correction with respect to the data. An arbitrary algorithm can be adopted as an algorithm of encoding and decoding using the ECC unit 13.

The quantum bit arithmetic unit 20, for example, is a semiconductor device having a NAND type cell structure, and is connected to the controller 10 through the NAND bus 15.

The NAND bus 15 transmits and receives a signal according to a NAND interface with respect to the quantum bit arithmetic unit 20. Specific examples of the signal include a chip enable signal CEn, an address latch enable signal ALE, a command latch enable signal CLE, a write enable signal WEn, a read enable signal REn, a ready and busy signal REn, an input and output signal I/O, and the like.

The signal CEn is a signal for enabling the quantum bit arithmetic unit 20. The signal CLE is a signal notifying the quantum bit arithmetic unit 20 that the input signal I/O is a command. The signal ALE is a signal notifying the quantum bit arithmetic unit 20 that the input signal I/O is an address. The signal WEn is a signal for incorporating the input signal I/O in the quantum bit arithmetic unit 20. The signal REn is a signal for reading the output signal I/O from the quantum bit arithmetic unit 20. The ready and busy signal RBn represents that the quantum bit arithmetic unit 20 is in a ready state (a state in which the command is capable of being received from the controller 10) or a busy state (a state in which the command is not capable of being received from the controller 10). The input and output signal I/O, for example, is 8 bits. The input and output signal I/O is the entity of the data which is transmitted and received between the quantum bit arithmetic unit 20 and the controller 10, and is a command, an address, writing data, reading data, or the like.

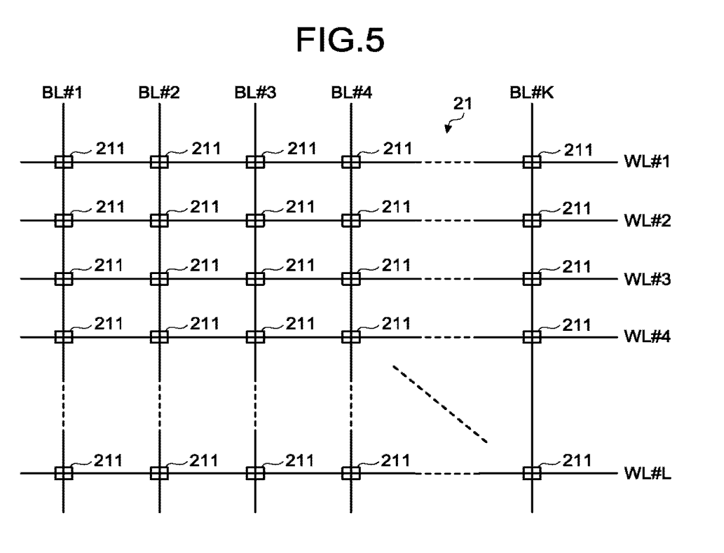

Subsequently, a more specific configuration of the quantum bit arithmetic unit 20 will be described by using FIG. 4 and FIG. 5. FIG. 4 is a block diagram illustrating a schematic configuration example of a quantum bit arithmetic unit according to this embodiment. FIG. 5 is a diagram illustrating a schematic configuration example of a quantum bit array illustrated in FIG. 4.

As illustrated in FIG. 4, the quantum bit arithmetic unit 20 includes a quantum bit array 21, a row decoder (R/D) 22, a driver circuit 23, a column module 24, an address register (an ADD register) 25, a command register (a CMD register) 26, and a sequencer 27.

As illustrated in FIG. 5, the quantum bit array 21 includes a plurality of word lines WL, a plurality of bit lines BL which intersect with the plurality of word lines WL by being separated up and down, and cells 211 as quantum bits which are connected to the word line WL and the bit line BL at each portion where the word line WL and the bit line BL are close to each other (hereinafter, referred to as a cross-point). Each of the cells 211, for example, is a semiconductor element having a floating gate structure, and is associated with a row and a column by the word line WL and the bit line BL. The quantum bit array 21 executes state searching while performing superposition of various states by using a tunneling effect due to a quantum fluctuation with respect to the data applied from the controller 10, and finally obtains a solution in which the cost function is set to a minimum value. Furthermore, the quantum bit array 21 may be divided into a plurality of blocks, which are an aggregate of the respective cells 211.

The row decoder 22 selects the word line WL (a row direction) of an access target of the quantum bit array 21. The driver circuit 23 supplies a voltage to the selected word line WL through the row decoder 22.

The column module 24, for example, is configured by including data latch formed of a sense amplifier and a plurality of latch circuits. The column module 24 transmits writing data DAT, which is received from the controller 10, to the quantum bit array 21, at the time of performing writing. In addition, the column module 24 senses the data, which is read from the quantum bit array 21, at the time of performing reading, and performs necessary arithmetic. Then, the column module 24 outputs the obtained data DAT to the controller 10.

The address register 25 retains an address ADD which is received from the controller 10. The command register 26 retains a command CMD which is received from the controller 10.

The sequencer 27 controls the entire operation of the quantum bit arithmetic unit 20, on the basis of the command CMD which is retained in the command register 26.

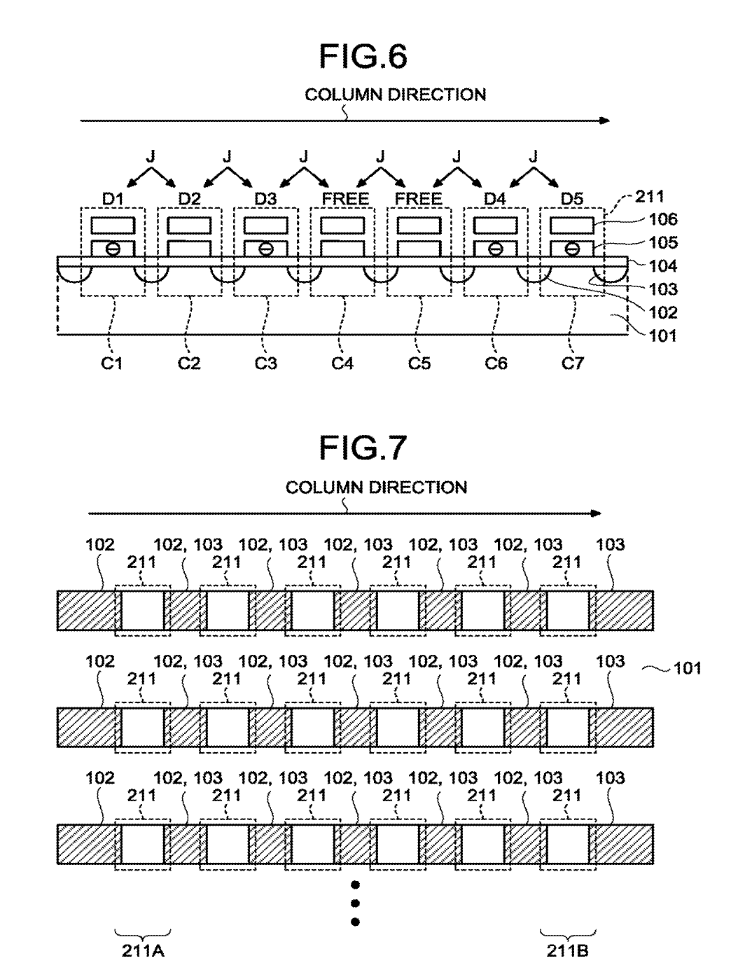

Subsequently, a structure and a quantum arithmetic operation of the cell 211 will be described. FIG. 6 is a diagram illustrating a configuration example of the cell (the quantum bit) according to this embodiment. Furthermore, FIG. 6 illustrates seven cells C1 to C7 which are arranged in a column direction of the common bit line BL. The cells C1 to C7 have a floating gate structure.

The cell 211 includes a semiconductor substrate 101, a tunneling film (also referred to as a tunnel oxide film or a gate insulating film) 104, two diffusion regions 102 and 103, a floating gate 105, and a control gate 106. The semiconductor substrate 101, for example, is a silicon substrate or the like. The tunneling film 104 is formed on a first surface of the semiconductor substrate 101 (referred to as an upper surface), and is an insulating film which functions as an electric potential barrier. Each of the diffusion regions 102 and 103, for example, is a region in which a dopant is diffused with respect to the semiconductor substrate 101, and functions as a source and a drain of the cell 211. The floating gate 105 is an electric charge retaining layer retaining an electric charge which enters from the semiconductor substrate 101 through the tunneling film 104. The control gate 106 is a gate electrode to which a voltage for controlling a threshold voltage or a tunneling effect of each of the cells 211 is applied. Thus, it is possible for each of the cells 211 according to this embodiment to have the same structure as that of a memory cell of the existing NAND type flash memory.

In the cell structure as described above, the number of electric charges retained in the floating gate 105 of each of the cells 211 represents a quantum state of each of the cells 211. Here, the electric charge indicates an electron or a hole. Therefore, data of ‘0’ and data of ‘1’ respectively correspond to a state where the number of electric charges of the cell is N (N is an integer of greater than or equal to 1) or N+1, or N or N−1 (N>1). An electric current flowing a lower region (a channel region) of the floating gate 105 on the semiconductor substrate 101 is changed according to the number of electric charges retained in the floating gate 105. Therefore, the number of electric charges retained in the floating gate 105 can be detected by measuring an electric current flowing between the diffusion regions 102 and 103 (the source and the drain).

In addition, as in this embodiment, in a case where the quantum bit array 21 is configured with the same layout as that of a memory cell array of the existing NAND type flash memory, the minute floating gate 105 is closely disposed. For this reason, an intercell interference based on a coulomb mutual interaction according to an intercell distance acts between the cells adjacent or close to each other in vertical and horizontal directions and an oblique direction (hereinafter, referred to as close cells) 211. Therefore, in this embodiment, an intercell interference effect is used as an ising mutual interaction between the cells. That is, in data where the optimization problem to be solved is described (hereinafter, referred to as initial data), data items to be combined by the ising mutual interaction are arranged (stored) in the close cell 211 where the intercell interference effect acts, and the data items having no mutual relationship are arranged (stored) in the cell 211 which is separated to the extent that the intercell interference effect does not act.

This will be described by using the example illustrated in FIG. 6. Furthermore, a case is assumed in which in initial data, there is a mutual relationship in data items D1 to D3, and there is a mutual relationship in data items D4 and D5, but there is no mutual relationship between the data items D1 to D3 and the data items D4 and D5. In such a case, the data items D1 to D3 are stored in close cells C1 to C3, and the data items D4 and D5 are stored in close cells C6 and C7. There is no mutual relationship between the data items D1 to D3 and the data items D4 and D5, and thus, one or more cells (hereinafter, referred to as free cells) not storing the data are arranged between the cells storing the data items D1 to D3 and the cells storing the data items D4 and D5. In the example of FIG. 6, the cells are interposed between the free cells C4 and C5, and thus, it is possible to treat each of the data items D1 to D3 and the data items D4 and D5 as an independent data aggregate.

In addition, FIG. 7 illustrates a top view of an example of a cell array having a NAND structure in the column direction. Furthermore, in the example illustrated in FIG. 7, the number of cells 211 combined in the column direction is 6, but it not limited thereto, and may be greater than or equal to 6, or may be less than or equal to 6. In a case of the NAND structure as exemplified in FIG. 7, the source 102 and the drain 103 between the cells 211 excluding the diffusion region 102 of the cell 211 positioned on the far left in the drawing (referred to as the source) and the diffusion region 103 of the cell 211 positioned on the far right in the drawing (referred to as the drain) electrically float from the semiconductor substrate 101. For this reason, for example, tunneling rarely occurs in two directions of a direction to the floating gate 105 from the semiconductor substrate 101 and a direction to the semiconductor substrate 101 from the floating gate 105 at the time of writing the data.

In such a configuration, it is possible to set an electric potential between the source 102 and the drain 103 to zero with respect to a column 211A of the cell 211 positioned on the far left in each row in the column direction, and similarly, a column 211B of the cell 211 positioned on the far right in each row in the column direction. Therefore, in such a case, in this embodiment, a configuration may be obtained such that a quantum annealing operation is realized by using two columns 211A and 211B.

In addition, in a case where a voltage to be applied to the control gate 106 is set to a voltage for reading data, and thus, the data is selectively read from a specific cell, it is possible to set the electric potential between the source 102 and the drain 103 to zero with respect to the cells 211 of columns other than the column 211A or 211B, and it is possible to use such cells 211 as a quantum annealing quantum bit.

As described above, in a case where the tunneling due to the quantum fluctuation occurs with respect to each of the cells 211 in which the initial data is arranged, the electric charge retained in the floating gate 105 of each of the cells 211 is moved such that the arrangement of the data (that is, the cost function) is energetically minimized (re-arrangement of the electric charge), The re-arrangement of the electric charge corresponds to a change in the state. Therefore, in this embodiment, the tunneling occurs for a certain period of time (also referred to as “tunneling is set to be ON”), and after that, the tunneling between the semiconductor substrate 101 and the floating gate 105 is blocked (also referred to as “tunneling is set to be OFF”). Accordingly, it is possible to realize a quantum annealing step.

As a result of such a quantum annealing step, the finally obtained data (electric charge arrangement), that is, the solution of the optimization problem, can be read as with a reading operation with respect to the memory cell having a floating gate structure.

Next, it will be described that the ising Hamiltonian H represented in Expression (2) can be described by an array of the cells 211 having a floating gate structure. In a case where the optimization problem of obtaining the ground state of the ising model is solved by the quantum annealing machine, as represented in Expression (2), the tunneling term Δ of controlling the strength and weakness of the tunneling effect due to the quantum fluctuation is added to the ising Hamiltonian H of Expression (1).

First two terms (the mutual interaction term Jᵢⱼ and the Zeeman term (Zeeman energy) hᵢ) of Expression (2) are derived from charging energy accompanied by the intercell interference. On the other hand, the tunneling term Δ on the tail end is derived from the tunneling of the electron between the semiconductor substrate 101 and the floating gate 105. At this time, note the following two points (A) and (B).

(A) a region in which a single electron effect of the floating gate is obtained is used in the quantum bit. In addition, a region in which the number of electrons in the floating gate can be counted is used in the quantum state. In such requirements, in a case of using the minute floating gate, it is possible to use a principle that the number of electrons in the floating gate can be counted. That is, in a case where the floating gate is miniaturized until a region is obtained in which capacitance is approximately 10E−18 F (Farad), the charging energy of the electron is in the order of several eV (electron volt), but in this region, the charging energy is greatly changed by being dependent on the number of electrons. For this reason, the electric current flowing through the channel region under the floating gate is measured, and thus, it is possible to use a technology that the number of electrons in the floating gate can be counted.

(B) the intercell interference is used in the mutual interaction between the quantum bits. The intercell interference strongly occurs as a distance between the floating gates which are adjacent or close to each other narrows. Therefore, in this embodiment, the intercell interference is actively used. That is, in this embodiment, the intercell interference effect is regarded as the ising mutual interaction, and the data items combined by the ising mutual interaction are arranged (stored) in the close cell in which the intercell interference effect acts.

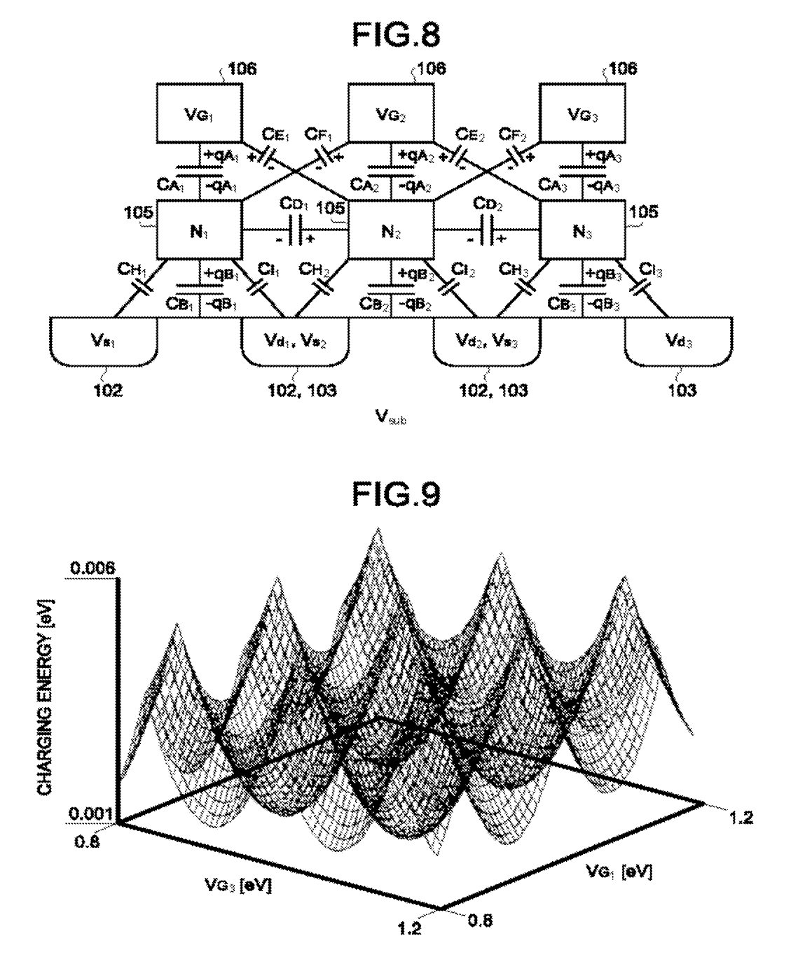

Subsequently, it will be described that the first two terms (the mutual interaction term Jᵢⱼ and the Zeeman term hᵢ) of Expression (2) can be described by the array of the cells 211 having a floating gate structure. Therefore, first, it will be described that the charging energy of the cell 211 includes the mutual interaction term Jᵢⱼ and the Zeeman term hᵢ, by using a capacitance network model exemplified in FIG. 8. A point in such description is that the charging energy of the cell 211 can be directly described by the mutual interaction term Jᵢⱼ and the Zeeman term hᵢ of Expression (2). Furthermore, a capacitance network configured of three cells 211 is exemplified in FIG. 8, and a calculation method to be described by using the example can be applied to a cell system having an arbitrary length.

With reference to the example illustrated in FIG. 8, Hamiltonian U of a charging energy portion in a capacitance network model configured of N cells 211 can be represented as the sum of the energy of the capacitance portion by using Expression (4) described below. Furthermore, in Expression (4), q is an electric charge, C is electrostatic capacitance, and V is a voltage. In addition, in the capacitance network model configured of N cells 211 to be arranged, a cell does not exist on one side of the N-th cell 211, and thus, q_{E}_{_}_{N+1}=q_{F}_{_}_{N+1}=0 is satisfied (suffixes after the underline “_” are subscripts. The same applies below).

$$U = \frac{1}{2} {\sum }_{i = 1}^{N} [ \frac{{q}_{{A}_{i}}^{2}}{{C}_{{A}_{i}}} + \frac{{q}_{{B}_{i}}^{2}}{{C}_{{B}_{i}}} + \frac{{q}_{{D}_{i}}^{2}}{{C}_{{D}_{i}}} + \frac{{q}_{{E}_{i}}^{2}}{{C}_{{E}_{i}}} + \frac{{q}_{{F}_{i}}^{2}}{{C}_{{F}_{i}}} + \frac{{q}_{{H}_{i}}^{2}}{{C}_{{H}_{i}}} + \frac{{q}_{{I}_{i}}^{2}}{{C}_{{I}_{i}}} ] - {\sum }_{i = 1}^{N} [ ( {q}_{{A}_{i}} + {q}_{{E}_{i}} + {q}_{{F}_{i - 1}} ) {V}_{i} + {q}_{{B}_{i}} {V}_{sub} + {q}_{{H}_{i}} {V}_{si} + {q}_{{I}_{i}} {V}_{dt} ] \qquad ( 4 )$$

From Expression (4) described above, the number of electrons Nᵢ in the floating gate 105 of the i-th cell 211 can be obtained from Expression (5) described below. Here, q_{D}_{_}₀=q_{E}_{_}₀=0 and V_{di}=V_{zi+1} are satisfied.

Nᵢ=−q_{A}_{ᵢ}+q_{B}_{ᵢ}−q_{D}_{ᵢ}+q_{D}_{_{i−1}}−q_{E}_{_{i−1}}−q_{F}_{ᵢ}+q_{H}_{ᵢ}+q_{I}_{ᵢ} (5)

Therefore, in order to obtain an electric charge distribution in which the charging energy of Expression (4) is minimized, a portion in the vicinity of a region represented by Expression (7) described below is considered by assuming Expression (6) described below. Furthermore, in Expression (6), various constants of Expression (11) described below are conveniently defined. Q and W are respectively an amount having energy unit.

$$\begin{matrix} {C}_{{a}_{1}} = {C}_{{A}_{1}} + {C}_{{B}_{1}} + {C}_{{D}_{1}} + {C}_{{F}_{1}} + {C}_{{H}_{1}} + {C}_{{I}_{1}} \\ {C}_{{a}_{2}} = {C}_{{A}_{2}} + {C}_{{B}_{2}} + {C}_{{D}_{2}} + {C}_{{F}_{2}} + {C}_{{H}_{2}} + {C}_{{I}_{2}} + {C}_{{D}_{1}} + {C}_{{E}_{1}} - \frac{{C}_{{D}_{1}}^{2}}{{C}_{{a}_{1}}} \\ {C}_{{a}_{3}} = {C}_{{A}_{3}} + {C}_{{B}_{3}} + {C}_{{D}_{3}} + {C}_{{F}_{3}} + {C}_{{H}_{3}} + {C}_{{I}_{3}} + {C}_{{D}_{2}} + {C}_{{E}_{2}} - \frac{{C}_{{D}_{2}}^{2}}{{C}_{{a}_{2}}} \\ {Q}_{{v}_{1}}^{0} = {C}_{{A}_{1}} {V}_{1} + {C}_{{B}_{1}} {V}_{sub} + {C}_{{F}_{1}} {V}_{2} + {C}_{{H}_{1}} {V}_{{s}_{1}} + {C}_{{I}_{1}} {V}_{{d}_{1}} \\ {Q}_{{v}_{2}}^{0} = {C}_{{A}_{2}} {V}_{2} + {C}_{{B}_{2}} {V}_{sub} + {C}_{{F}_{2}} {V}_{3} + {C}_{{H}_{2}} {V}_{{s}_{2}} + {C}_{{I}_{2}} {V}_{{d}_{2}} \\ {Q}_{{v}_{3}}^{0} = {C}_{{A}_{3}} {V}_{3} + {C}_{{B}_{3}} {V}_{sub} + {C}_{{H}_{3}} {V}_{{s}_{3}} + {C}_{{I}_{3}} {V}_{{d}_{3}} \\ {W}_{1} = {C}_{{A}_{1}} {V}_{1}^{2} + {C}_{{B}_{1}} {V}_{sub}^{2} + {C}_{{F}_{1}} {V}_{2}^{2} + {C}_{{H}_{1}} {V}_{{s}_{1}}^{2} + {C}_{{I}_{1}} {V}_{{d}_{1}}^{2} \\ {W}_{2} = {C}_{{A}_{2}} {V}_{2}^{2} + {C}_{{H}_{2}} {V}_{sub}^{2} + {C}_{{F}_{2}} {V}_{3}^{2} + {C}_{{H}_{2}} {V}_{{s}_{2}}^{2} + {C}_{{I}_{2}} {V}_{{d}_{2}}^{2} \\ {W}_{3} = {C}_{{A}_{3}} {V}_{3}^{2} + {C}_{{B}_{3}} {V}_{sub}^{2} + {C}_{{H}_{3}} {V}_{{s}_{3}}^{2} + {C}_{{I}_{3}} {V}_{{d}_{3}}^{2} & ( 6 ) \\ {( {N}_{i} + {Q}_{{v}_{i}}^{0} )}^{2} = {( {N}_{i} + 1 + {Q}_{{v}_{i}}^{0} )}^{2} & ( 7 )\end{matrix}$$

The region represented by Expression (7) is a region in which the charging energy at the number of electrons Nᵢ and the charging energy at the number of electrons Nᵢ₊₁ are equal to each other, and is a region in which a superposition state between a state |Nᵢ> and a state |Nᵢ₊₁> occurs. Here, n_{gi} is defined by Expression (8). n_{gi} is a value which is changed along with the gate voltage.

$${N}_{{i}_{i}} + {Q}_{{v}_{j}} = {n}_{g , i} - \frac{1}{2} \qquad ( 8 )$$

In the portion in the vicinity of the region represented by Expression (7), the charging energy term Jᵢⱼ is represented by Expression (9) described below, by using

$${\sum }_{{N}_{i}} {( {N}_{i} + {Q}_{{v}_{i}}^{0} )}^{2} \to {( {n}_{gi} - \frac{1}{2} )}^{2} \vert {N}_{i} 〉 〈 {N}_{t} \vert + {( {n}_{gi} + \frac{1}{2} )}^{2} \vert {N}_{i} + 1 〉 〈 {N}_{i} + 1 = \frac{1}{2} {n}_{gi} {σ}_{i}^{z} + ( {n}_{gi}^{2} + \frac{1}{4} ) {I}_{i} \qquad ( 9 )$$

In Expression (9), σᵢ^{z} and Iᵢ are respectively a Pauli matrix and an identity matrix, which are based on {|Nᵢ₊₁>, |Nᵢ>}, and are represented by Expression (10) described below.

σᵢ^{z}=−|Nᵢ [symbol] [symbol] Nᵢ|+|Nᵢ+1 [symbol] [symbol] Nᵢ+1|

Iᵢ=|Nᵢ [symbol] [symbol] Nᵢ|+|Nᵢ+1 [symbol] [symbol] Nᵢ+1| (10)

As described above, the Hamiltonian U of the charging energy portion can be represented by Expression (11) described below.

$$U = \frac{1}{2} {\sum }_{i = 1}^{2} [ \frac{1}{{C}_{{a}_{i}}} ( 1 + \frac{{C}_{{D}_{i}}^{2}}{{C}_{{a}_{i}} {C}_{{a}_{i + 1}}} ) {n}_{gi} + \frac{1}{{C}_{{a}_{i}} {C}_{{a}_{i + 1}}} ( {C}_{{D}_{i - 1}} {n}_{gi - 1} + {C}_{{D}_{i}} {n}_{gi + 1} ) ] {σ}_{i}^{z} + \frac{1}{2} [ \frac{1}{{C}_{{a}_{3}}} {n}_{g 3} + \frac{{C}_{{D}_{2}}}{{C}_{{a}_{2}} {C}_{{a}_{3}}} {n}_{g 2} ] {σ}_{3}^{z} + {\sum }_{i = 1}^{2} \frac{{C}_{{D}_{i}}}{4 {C}_{{a}_{i}} {C}_{{a}_{i + 1}}} {σ}_{i}^{z} {σ}_{i + 1}^{z} + \frac{1}{2} {\sum }_{i = 1}^{2} [ \frac{1}{{C}_{{a}_{i}}} ( 1 + \frac{{C}_{{D}_{i}}^{2}}{{C}_{{a}_{i}} {C}_{{a}_{i + 1}}} ) ( {n}_{gi}^{2} + \frac{1}{4} {I}_{i} ) - {W}_{i} ] + \frac{1}{2 {C}_{{a}_{3}}} ( {n}_{g 3}^{2} + \frac{1}{4} ) {I}_{3} - \frac{{W}_{3}}{2} + {\sum }_{i = 1}^{2} \frac{{C}_{{D}_{i}}}{{C}_{{a}_{i}} {C}_{{a}_{i + 1}}} {I}_{i} {I}_{i + 1} \qquad ( 11 )$$

Expression (11) corresponds to the portion of the classic ising Hamiltonian H represented in Expression (2) (refer to Expression (12) described below).

$${\sum }_{j = 1}^{3} {h}_{j} {σ}_{j}^{z} + {J}_{12} {σ}_{1}^{z} {σ}_{2}^{z} + {J}_{23} {σ}_{2}^{z} {σ}_{3}^{z} + Const . \qquad ( 12 )$$

Therefore, the mutual interaction term Jᵢⱼ and the magnetic field term hᵢ of Expression (2) can be respectively represented by Expression (13) described below.

$${J}_{ij} = \frac{{C}_{{D}_{i}}}{4 {C}_{{a}_{i}} {C}_{{a}_{j}}} \\ {h}_{i} = \frac{1}{2 {C}_{{a}_{i}}} ( 1 + \frac{{C}_{{D}_{i}}^{2}}{{C}_{{a}_{i}} {C}_{{a}_{i + 1}}} ) {n}_{gi} + \frac{1}{2 {C}_{{a}_{i}} {C}_{{a}_{i + 1}}} ( {C}_{{D}_{i - 1}} {n}_{gi - 1} + {C}_{{D}_{i}} {n}_{gi + 1} ) \qquad ( 13 )$$

In the input of actual initial data, in a case where there is a mutual relationship between two data items, such data is stored in the floating gate 105 of the cells 211 which are adjacent or close to each other. In this case, the intercell interference occurs between the cells 211, and J is finite. On the other hand, in a case where there is no mutual relationship between two data items, the data is stored in the cells 211 which are not adjacent, or close to each other (cells through one or more free cells in the vertical and horizontal directions and/or the oblique direction). Furthermore, a case is exemplified in FIG. 8 in which the semiconductor substrate 101 of each of the cells 211 is controlled by a common substrate voltage V_{sub}, and each of the cells 211 can be configured to be controlled by different substrate voltages V_{sub} by adopting a structure in which the cells 211 are element-separated from each other.

FIG. 9 illustrates an example of a calculation result in a case where a gate voltage is not applied to the control gate 106 of the central cell 211 (V_{G}_{_}₂=0), in the capacitance network model exemplified in FIG. 8. Each parabola represents the unique number of electrons. That is, each of the parabolas represents a state in a case where the number of electrons is constant. When the parabolas overlap with each other, Expression (7) is established, and the number of electrons is changed by one. At this time, the number of electrons is changed such that the charging energy of the electron is minimized. In the quantum annealing, the change in the state according to the movement of the electron superimposed, and thus, finally, the state in which the charging energy of the electron, which is the cost function, is minimized, is output as a solution.

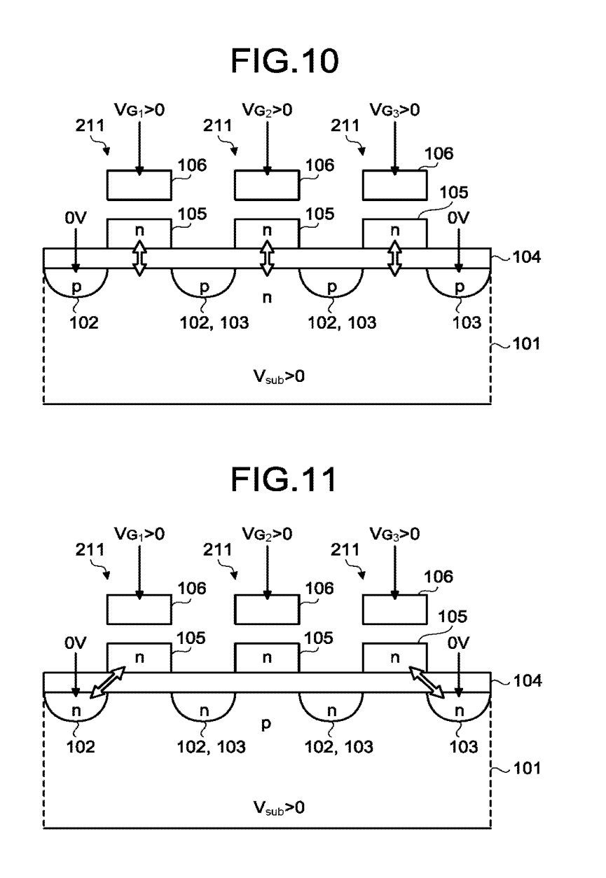

Subsequently, the derivation of the tunneling term Δ represented in Expression (2) will be described. In the general NAND type flash memory, the electron is moved into the floating gate 105 from the semiconductor substrate 101 at the time of performing writing, and the electron is moved into the semiconductor substrate 101 from the floating gate 105 at the time of performing erasing. Here, the movement of the electric charge through the tunneling film 104, that is, the tunneling itself is a quantum phenomenon. In order to allow Expression (1) to develop to Expression (2) by using the tunneling, it is necessary that the electron travels between the semiconductor substrate 101 and the floating gate 105 with the same probability. Such a phenomenon, for example, is capable of being realized by decreasing the electric potential of the tunneling film 104. In FIG. 10 and FIG. 11, an aspect is illustrated in which the electron travels between the semiconductor substrate 101 and the floating gate 105 with the same probability by decreasing the electric potential of the tunneling film 104.

In the description of FIG. 10 and FIG. 11, a tunneling portion can be represented as Expression (14) described below, by using WKB approximate, which is one of the semi-classical approximate solution methods of a Schrodinger equation. Here, ρ_{L} and ρ_{R} are respectively state density of the electrons of the floating gate 105 and the semiconductor substrate 101. In addition, k and k′ are respectively a wave number vector of the floating gate 105 and the semiconductor substrate 101, and δᵢⱼ is a Kronecker delta. Further, x is a position on a straight line including a line segment connecting the semiconductor substrate 101 and the floating gate 105 together at the shortest distance, and k(x) is a wave vector given by √(2m(E−V(x)). Furthermore, m is the mass of the electron, V(x) is the potential energy of the electron, E is the energy of the electron which is moved in an x direction.

$$\vert {Δ}_{{kk}^{′}} {\vert}^{2} = \frac{1}{4 {π}^{2}} \frac{{δ}_{{kk}^{′}} {δ}_{{kk}_{F}}}{{ρ}_{R} {ρ}_{L}} exp [ - 2 {\int }_{{x}_{l}}^{{x}_{r}} {k}_{v} ( x ) dx ] \qquad ( 14 )$$

Therefore, the tunneling term Δ represented by Expression (2) can be represented by Expression (15) described below. Here, C_{kR} and C_{kL} are respectively an annihilation operator of the electron in the floating gate 105 and the semiconductor substrate 101, C_{kR}^{t} is a Hermitian conjugate of C_{kR},

[symbol]

is a Planck constant, and Lₓ is a film thickness of a portion in the floating gate 105, which contributes to the tunneling.

$${\sum }_{k , {k}^{′}} {Δ}_{k , {k}^{′}} {C}_{kR}^{†} {C}_{kL} \approx {Vol}^{2} \int \frac{{d}^{3} k}{{( 2 π )}^{3}} \int \frac{{d}^{3} {k}^{′}}{{( 2 π )}^{3}} \frac{{ℏ}^{2}}{2 m} \frac{{k}_{x}}{{L}_{x}} exp [ - {\int }_{{x}_{l}}^{{x}_{r}} {k}_{v} ( x ) dx ] {δ}_{{k}_{x} , {k}_{x}^{′}} {c}_{R}^{†} {c}_{L} = {N}_{L} {N}_{R} {{R}_{y} ( \frac{π {a}_{0}}{{L}_{x}} )}^{2} \frac{{m}_{0}}{{m}_{xi}} exp [ - \frac{{d}_{ox}}{{a}_{0}} \sqrt{\frac{{V}_{ox} - E}{{R}_{y}} ( \frac{{m}_{ox}}{{m}_{0}} )} ] {c}_{R}^{†} {c}_{L} \qquad ( 15 )$$

Furthermore, in Expression (15), N_{L} and N_{R} are the number of electrons relevant to the tunneling between the floating gate 105 and the semiconductor substrate 101. dₒₓ and Vₒₓ are a film thickness and a potential height of the tunneling film 104. mₓᵢ and mₒₓ are the mass of the electron in the semiconductor substrate 101 and in the tunneling film 104 (insulating film), and m₀ is the mass of the electron in vacuum. In addition, a₀=0.052918 nm is a Bohr radius, and R_{y}=13.605698 eV is a Rydberg constant.

Here, for example, in a case where the tunneling coefficient is set to N_{R}=N_{L}=1 at the time of Lₓ=15 nm, dₒₓ=3 nm, and Vₒₓ−E=2.5 eV, the tunneling term Δ is 3.598E−9 eV. In addition, in a case of Vₒₓ−E=1.5 eV, the tunneling term Δ is 2.279E−7 eV.

Here, as it is obvious from Expression (15), an occurrence probability of the tunneling is rapidly reduced with respect to an increase in the film thickness dₒₓ of the tunneling film 104. This indicates that the film thickness dₒₓ is an element for determining the order of a period where the tunneling is set to be ON in the quantum annealing step. Therefore, in this embodiment, the film thickness dₒₓ, for example, is less than or equal to 3 nm. Accordingly, it is possible to reduce the length of arithmetic time due to a decrease in the occurrence probability of the tunneling.

In addition, the polarity of the electric charge allowing the tunneling to occur is determined according to a combination between the polarity of the floating gate 105 with the polarity of the semiconductor substrate 101. FIG. 10 illustrates a case where both of the semiconductor substrate 101 and the floating gate 105 have an n type polarity (for example, the polarity of the dopant). In this case, the tunneling occurs between the floating gate 105 and the semiconductor substrate 101 having the same n type polarity. Here, in a case where both of the semiconductor substrate 101 and the floating gate 105 have a p type polarity, the electric charge allowing the tunneling to occur is a hole of a positive electrode.

On the other hand, FIG. 11 illustrates a case where the polarity of the semiconductor substrate 101 is different from the polarity of the floating gate 105. FIG. 11 illustrates a case where the semiconductor substrate 101 has the p type polarity, and the floating gate 105 has the n type polarity. In this case, the tunneling occurs between the n type floating gate 105 and the n type diffusion region 102 (referred to as a source) and/or the diffusion region 103 (referred to as a drain). The electric charge allowing the tunneling to occur is an electron of a negative electrode. Here, the semiconductor substrate 101 has the n type polarity, and the floating gate 105 has the p type polarity, the electric charge allowing the tunneling to occur is the hole of the positive electrode.

Furthermore, FIG. 11 illustrates a case of three arranged cells 211, in order to simplify the description. Here, the configuration is not limited to the configuration illustrated in FIG. 11, and for example, the number of central cells 211 interposed between the cells 211 on both ends can be greater than or equal to 2.

Here, in the general NAND type flash memory, as illustrated in FIG. 7, a plurality of cells are arranged in the column direction. For this reason, sources and drains, which are capable of applying a voltage, are limited to the diffusion regions 102 and 103 positioned on both ends of the arrangement. In this case, sources and drains of cells other than the cells both ends are in a floating state. Accordingly, a voltage between the source and the drain is different for each of the cells 211 according to the voltage applied to the control gate 106. By using such a configuration, it is possible to set the electric potential of the diffusion regions 102 and 103 of the central cell 211 in FIG. 11 to be greater than the substrate voltage V_{sub}. As a result thereof, it is possible to prevent the electric current from flowing to the diffusion regions 102 and 103 of the central cell 211 from the p type semiconductor substrate 101.

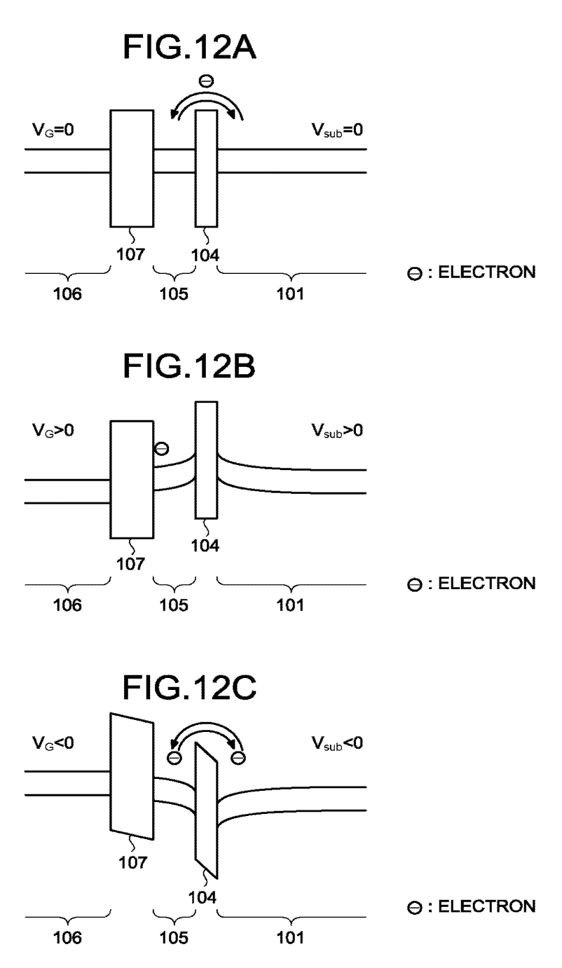

FIG. 12A to FIG. 12C illustrate energy band diagrams for illustrating an aspect in which the tunneling of the electron occurs under the condition illustrated in FIG. 10. Furthermore, in FIG. 12A to FIG. 12C, a case is exemplified in which the semiconductor substrate 101 and the floating gate 105 have the same dopant concentration, but the concentrations may be different from each other. In addition, in FIG. 12A to FIG. 12C, a reference numeral 107 illustrates an insulating film interposed between the floating gate 105 and the control gate 106. Further, in the configuration exemplified in FIG. 12A to FIG. 12C, on the basis of source/drain voltages Vₛ and V_{d}, the switching of ON and OFF of the tunneling can be realized by relatively changing the voltages V_{G} and V_{sub}.

In a switching mechanism of ON/OFF of the tunneling, there are two types of mechanisms according to the thickness of the tunneling film 104. For example, in a case where the tunneling film 104 is thinner than approximately 3 nm, as illustrated in FIG. 12A, the tunneling occurs between the floating gate 105 and the semiconductor substrate 101 when the gate voltage and the substrate voltage are not applied. This will be referred to as a normally-on type mechanism. In the normally-on type mechanism, as illustrated in FIG. 12B, in a case where the voltages V_{G} and V_{sub} are applied, a band is bent. Accordingly, a film thickness of the tunneling film 104 (also referred to as a tunnel film thickness) effectively increases, and as a result thereof, the tunneling is set to be OFF.

On the other hand, in a case where the tunneling film 104 is thicker than approximately 3 nm, as illustrated in FIG. 12C, the film thickness of the tunneling film 104 is effectively reduced when the gate voltage and the substrate voltage are applied, and as a result thereof, the tunneling is set to be ON. This will be referred to as a normally-off type mechanism. In such a normally-off type mechanism, the tunneling film 104 is comparatively thick, and thus, when V_{G}=0 and V_{sub}=0 are satisfied, the probability that the tunneling occurs is extremely low, and the tunneling is substantially set to be OFF.

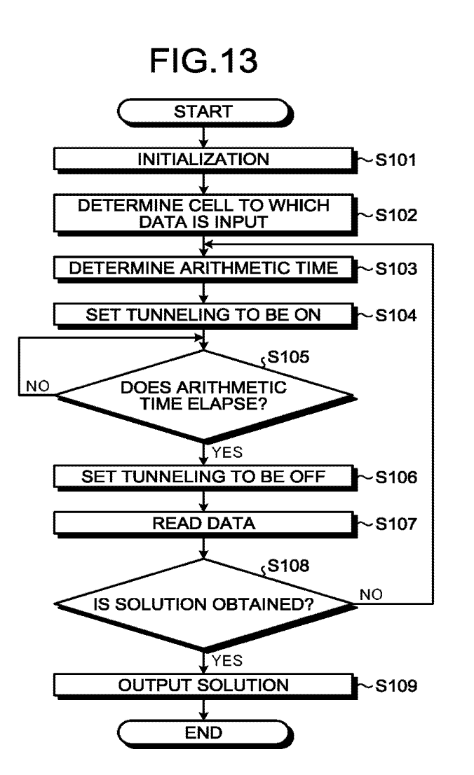

Subsequently, the quantum arithmetic operation executed by the quantum annealing machine 1 according to this embodiment will be described. FIG. 13 is a flowchart illustrating an example of the quantum arithmetic operation according to this embodiment. Furthermore, in FIG. 13, the operation of the CPU 11 illustrated in FIG. 3 will be mainly described.

In this operation, the CPU 11, first, issues a command of erasing the data stored in each of the cells 211 to the program/read IF/14, and thus, initializes the quantum bit array 21 (S101). The program/read I/F 14 issues a command of erasing the data in the quantum bit array 21 to the quantum bit arithmetic unit 20, and thus, the data in the quantum bit array 21 is erased.

Next, the CPU 11 determines the cell 211 to which the data is input, on the basis of the initial data in which the optimization problem to be solved is described (S102). Furthermore, a determination method of the cell 211 to which the data is input is identical the method described by using FIG. 6, and thus, the description thereof will be omitted herein. In addition, the initial data, for example, is input in advance from the external device or the like, and is stored in the RAM 12 or the like. However, the embodiment is not limited thereto, and may be configured such that notice of the arrangement of the data determined from the initial data is given to the CPU 11 in the external device. In this case, the CPU 11 determines the cell 211 from the arrangement of the data.

Next, the CPU 11 determines time when the quantum arithmetic is executed, that is, time when the tunneling is set to be ON (hereinafter, referred to as arithmetic time) (S103). It is preferable that the arithmetic time is time when the cost function of the optimization problem to be solved is the minimum value, that is, necessary and sufficient time for setting the electric charge arrangement of the quantum bit array 21 to be in a minimum energy state. Furthermore, from the viewpoint of obtaining several solutions, the arithmetic time may be time when the tunneling stochastically occurs at least one time. In addition, the arithmetic time may be configured to be suitably set by a user.

Next, the CPU 11 issues a command of setting the tunneling in the quantum bit array 21 to be ON to the program/read I/F 14 (S104). More specifically, the CPU 11 issues a command of applying a voltage waveform scheduled such that the tunneling effect is attenuated as time elapses to each of the cells 211 to the control gate 106 to the program/read I/F 14. The program/read I/F 14 issues a command of applying the voltage waveform to each of the cells 211 to the quantum bit arithmetic unit 20. As a result thereof, the tunneling in the quantum bit array 21 is set to be ON, and thus, the arithmetic according to the quantum annealing is executed.

After that, the CPU 11 waits until the determined arithmetic time elapses (S105; NO), and in a case where the arithmetic time elapses (S105; YES), issues a command of setting the tunneling to be OFF to the program/read I/F 14 (S106). The program/read I/F 14 issues a command of stopping the applying of the voltage waveform to the quantum bit arithmetic unit 20. As a result thereof, the tunneling in the quantum bit array 21 is set to be ON, and the arithmetic according to the quantum annealing is stopped.

Next, the CPU 11 issues a command of reading the data from the quantum bit array 21 to the program/read I/F 14 (S107). The program/read I/F 14, for example, reads the data from the quantum bit arithmetic unit 20 according to the same reading operation as that of the general NAND type flash memory. Furthermore, the read data, for example, is stored in the RAM 12 or the like after the error correction is executed by the ECC unit 13.

Next, the CPU 11 analyzes the read data, and thus, determines whether or not a sufficient solution is obtained (S108), and in a case where the sufficient solution is obtained (S108; YES), for example, the obtained solution is output to the external device (S109), and this operation is ended. On the other hand, in a case where the sufficient solution is not obtained (S108; NO), the CPU 11 returns to S103, and determines again the arithmetic time, and then, the subsequent operation is executed. Furthermore, the sufficient solution, for example, may be a solution of sufficiently decreasing the cost function of the optimization problem to be solved, and the like. In addition, a return destination in a case where the sufficient solution is obtained (S108; NO) is not limited to S103, and for example, may be any one of S101 to S104.

As described above, according to this embodiment, the quantum annealing machine is configured by using the floating gate type cell 211 which is used in the established technology such as a NAND type flash memory, and thus, it is possible to realize an information processing device as the quantum annealing machine having high mass productivity and high reliability, an information processing system, and an information processing method.

In addition, according to this embodiment, the FG type memory, in which a production technology is previously established and which is commercialized, is used as a base, and thus, it is not necessary to change the design of a mask, and the like. As a result thereof, it is possible to manufacture the information processing device as the quantum annealing machine, the information processing system, and the information processing method at low cost.

Further, in this embodiment, a so-called electric charge quantum bit is used from the aspect of the quantum bit. That is, in a case where the number of electrons stored in the minute floating gate is small, a so-called single electron effect occurs, but in this embodiment, a state where the single electron effect occurs is treated as the quantum state, and thus, the tunneling term Δ of Expression (2) is actually a change in the number of electrons through the tunneling film 104. In the electric charge quantum bit, the electric charge is easily affected by a noise or the like, and coherence time is also short, but complete coherence is not necessary in the quantum annealing machine, and thus, in this embodiment, the electric charge quantum bit is realized by the same structure as that of the NAND type flash memory, and therefore, it is possible to realize the information processing device as the quantum annealing machine which is capable of realizing the overwhelming arithmetic capacity in the integration degree, the information processing system, and the information processing method.

Furthermore, in the optimization problem, the number of data items to be combined with one data item is arbitrary. That is, in Expression (2), the number of cells j, in which the mutual interaction term Jᵢⱼ with respect to a certain cell ᵢ is not zero, is arbitrary. On the other hand, for example, in a memory cell array where the memory cells such as the general NAND type flash memory are two-dimensionally arranged (also referred to as a flat floating gate array), in the adjacent cells in the vertical and horizontal directions or the oblique direction, the number of cells to be combined with the certain cell by the mutual interaction between the cells based on the coulomb mutual interaction according to the intercell distance is 4 in the vertical and horizontal directions, and is a maximum of 8 by including the cells in the oblique direction. For this reason, in a case of configuring the quantum annealing machine 1 by using flat floating gate array, a physical mutual interaction can be formed in the maximum of eight adjacent cells with respect to the certain cell, but in order to form the physical mutual interaction in nine or more cells, it is necessary to introduce a relationship between two cells as a logic circuit. That is, it is necessary to design a model between two cells which are spatially separated to the extent that the physical mutual interaction is not formed such that the cost function (the energy) of Expression (2) is an effectively different value, in a case where the two cells are simultaneously ‘0’ or simultaneously ‘1’ and a case where the two cells have a value different from ‘0’ and ‘1’.

In such a case, the values between the cells 211 which are not adjacent or close to each other in the quantum bit array 21 are compared to each other, and an operation is executed such that in a case where the data is 0 and 0, or 1 and 1, the energy (or the cost function) increases by J, and in a case where the data is 0 and 1, the energy (or the cost function) decreases by J.

### Second Embodiment

In the first embodiment, the mutual interaction between the cells 211 which are adjacent or close to each other has been described as the constant value which is determined by the distance between the cells, or the like. However in order to solve various optimization problems, there is a case where it is convenient that the value of the mutual interaction (a combination constant) J of Expression (2) is a positive or a negative real number. Therefore, in a second embodiment, a case where the value of J of Expression (2) is the positive or the negative real number will be described as an example.

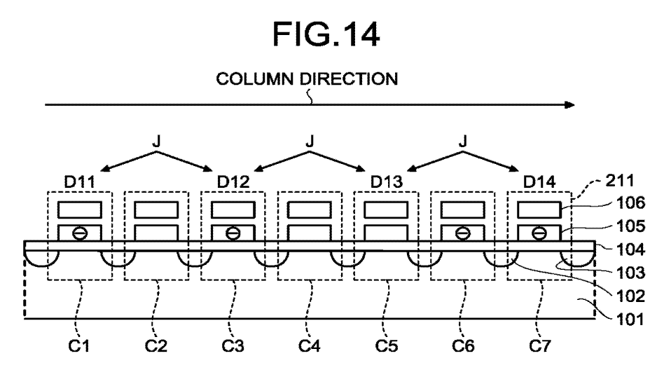

FIG. 14 is a diagram for illustrating the concept of this embodiment, and is a diagram illustrating a configuration example of the cell (the quantum bit). Furthermore, FIG. 14 illustrates seven cells C1 to C7 which are connected to the common word line WL and are arranged in the column direction, as with FIG. 6. The cells C1 to C7 have a floating gate structure. Furthermore, a combination structure of the cells as illustrated in FIG. 14 is not limited to the column direction, and can be applied to the row direction.

In the cell structure exemplified in FIG. 14, for example, a radio frequency voltage is applied to the cells C2, C4, and C6, and thus, the combination constant J having an arbitrary size can be set between the cells C1 and C3, the cells C3 and C5, and the cells C5 and C7. Hereinafter, the combination constant between the cell C1 and the cell C3 will be mainly described.

For example, by using a technology disclosed in Non Patent Literature 6, it is possible to freely change the combination constant J. Therefore, the radio frequency voltage to be applied to the cell C2 is a voltage represented by Expression (16) described below.

$${H}_{hf} = {\sum }_{j = 1}^{3} δ {h}_{j} ( t ) {σ}_{j}^{2} \qquad ( 16 )$$

At this time, it is necessary to apply the radio frequency voltage to the floating gate 105 each of the cells C1 to C7. Here, a new combination state between the cell C1 and the cell C3 will be represented by assuming a case where the central cell 211 in three arranged cells 211 is set to a cell (a junction ceil) for combining the cells 211 on both ends (in the following expression, j=1, 2, and 3). Therefore, in a case of obtaining a result by defining Expression (17) described below, Expression (18) described below can be obtained, as with Non Patent Literature 6. Furthermore, the character with tilde (˜) is an effective physical amount of a rotating coordinate system.

$$\begin{matrix} {ω}_{j} = \sqrt{{Δ}_{h}^{2} + {h}_{j}^{2}} & ( 17 ) \\ {\tilde{h}}_{j} = {h}_{j} + \frac{2 {h}_{2} ( t ) {J}_{j 2}}{{ω}_{2} ( t )} \\ {\tilde{Δ}}_{j} = {Δ}_{j} - \frac{2 {( {J}_{j 2} {Δ}_{2} )}^{2} {Δ}_{j}}{{{ω}_{2} ( t )}^{2} - {Δ}_{j}^{2} - {h}_{j}^{2}} \\ {\tilde{J}}_{13} ( t ) = {J}_{13} + \frac{{J}_{23} {J}_{12} {Δ}_{2}^{2}}{{{ω}_{2} ( t )}^{3}} ( \frac{{{ω}_{2} ( t )}^{2} - {h}_{3}^{2}}{{{ω}_{2} ( t )}^{2} - {Δ}_{3}^{2} - {h}_{3}^{2}} \frac{{{ω}_{2} ( t )}^{2} - {h}_{1}^{2}}{{{ω}_{2} ( t )}^{2} - {Δ}_{1}^{2} - {h}_{1}^{2}} ) & ( 18 )\end{matrix}$$

As it is obvious from Expression (18), according to this embodiment, the radio frequency voltage to be applied to the cell C2 interposed between two cells C1 and C3 for combination is adjusted, and thus, the combination constant J of the cells C1 and C3 can be set to an arbitrary value.

Other configurations, operations, and effects are identical to those of the embodiment described above, and thus, the detailed description will be omitted herein.

Furthermore, in the embodiment described above, a case where the structure of the NAND type flash memory is adopted in a connection structure between the quantum bits has been mainly described, but the embodiment is not limited to such a structure. For example, a connection structure of a NOR type flash memory can also be adopted. In this case, the diffusion electrodes 102 and 103 shared between the adjacent cells 211 can be substituted with two diffusion regions 102 and 103 which are independent from each other by element separation or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An information processing device, comprising:
a quantum bit array that includes a plurality of quantum bits respectively including a floating gate; and
a controller that executes writing of data in the plurality of quantum bits and reading of the data from the plurality of quantum bits, and temporally controls tunneling of an electric charge with respect to the floating gate.

2. The information processing device according to claim 1,
wherein the controller temporally controls the tunneling of the electric charge with respect to the floating gate such that the tunneling of the electric charge stochastically occurs at least one time.

3. The information processing device according to claim 2,
wherein the plurality of quantum bits respectively includes,
a semiconductor substrate,
a source and a drain disposed on the semiconductor substrate,
the floating gate disposed on a region interposed between the source and the drain in the semiconductor substrate,
an insulating film electrically separating the semiconductor substrate from the floating gate by being interposed between the semiconductor substrate and the floating gate, and
a control gate disposed on a side opposite to the semiconductor substrate through the floating gate by being separated from the floating gate, and
the controller controls time when an electric potential in the vicinity of the insulating film between the floating gate and the semiconductor substrate is an electric potential different from both of an electric potential of a position separated from the insulating film in the semiconductor substrate and an electric potential of the control gate, and thus, the tunneling of the electric charge stochastically occurs at least one time.

4. The information processing device according to claim 1,
wherein the quantum bit array includes a plurality of word lines, and a plurality of bit lines intersecting with the plurality of word lines by being separated up and down,
the plurality of quantum bits are connected to the word line and the bit line at each cross-point at which the word line and the bit line are close to each other, and
in a first quantum bit to a third quantum bit commonly connected to the plurality of word lines, the controller sets the first quantum bit and the third quantum bit as a cell storing initial data, and sets the second quantum bit interposed between the first quantum bit and the third quantum bit as a cell controlling a mutual interaction between the first quantum bit and the third quantum bit.

5. The information processing device according to claim 3,
wherein a film thickness of the insulating film is less than or equal to 3 nm (nanometers).

6. The information processing device according to claim 1,
wherein the quantum bit array includes a plurality of word lines, and a plurality of bit lines intersecting with the plurality of word lines by being separated up and down,
the plurality of quantum bits are connected to the word line and the bit line at each cross-point at which the word line and the bit line are close to each other,
in a plurality of quantum bits connected to a common word line among the plurality of quantum bits, quantum bits other than quantum bits of both ends share the source or the drain between adjacent quantum bits, and
in the plurality of quantum bits connected to the common word line, the controller sets the quantum bits of the both ends as a cell storing initial data, and sets a quantum bit interposed between the quantum bits of the both ends as a cell controlling a mutual interaction between the quantum bits of the both ends.

7. The information processing device according to claim 1,
wherein the controller effectively calculates energy of each of the quantum bits from a value between quantum bits, which are not adjacent or close to each other, in the quantum bit array, and sets the calculated energy as a Hamiltonian constant of quantum annealing.

8. An information processing system, comprising:
a quantum bit arithmetic unit that includes a quantum bit array including a plurality of quantum bits, the plurality of quantum bits respectively including a floating gate; and
a controller that is connected to the quantum bit arithmetic unit, executes writing of data in the plurality of quantum bits and reading of the data from the plurality of quantum bits, and temporally controls tunneling of an electric charge with respect to the floating gate.

9. An information processing method of obtaining a solution of an optimization problem by using a quantum bit array including a plurality of quantum bits, the plurality of quantum bits respectively including a floating gate, the method comprising:
writing initial data in one or more quantum bits of the plurality of quantum bits;
temporally controlling tunneling of an electric charge with respect to the floating gate in the quantum bit; and
reading data from the plurality of quantum bits.
